(19) United States
(12) Patent Application Publication
(10) Pub. No.: US 2009/0134448 A1
(43) Pub. Date: May 28, 2009

(54) Non-volatile memory device and method of forming the same

(76) Inventors: Taek-Soo Jeon, Yongin-si (KR); Si-Young Choi, Seongnam-si (KR); In-Sang Jeon, Seoul (KR); Sang-Bom Kang, Seoul (KR); Si-Hyung Lee, Suwon-si (KR); Seung-Hoon Hong, Seoul (KR)

Correspondence Address: HARNESS, DICKEY & PIERCE, P.L.C., P.O. BOX 8910, RESTON, VA, 20195, US

(21) Appl. No.: 12/230,835

(22) Filed: Sep. 5, 2008

(30) Foreign Application Priority Data
Sep. 6, 2007 (KR) 10-2007-090615

(51) Int. Cl. H01L 29/68; H01L 21/336

(52) U.S. Cl. 257/324; 438/591; 257/E29.17; 257/E21.423

(57) ABSTRACT

Example embodiments provide a non-volatile semiconductor memory device and method of forming the same. The non-volatile memory device may include a tunnel insulation layer on a semiconductor substrate, a charge storage layer on the tunnel insulation layer, a first blocking insulation layer on the charge storage layer, and a gate electrode on the first blocking insulation layer, wherein the gate electrode includes aluminum and the first blocking insulation layer does not include aluminum.

### PRIORITY STATEMENT

This application claims priority under 35 U.S.C § 119 to Korean Patent Application No. 10-2007-0090615, filed on Sep. 6, 2007, in the Korean Patent Office, the entire contents of which are incorporated by reference.

### BACKGROUND

1. Field

Example embodiments are related to a semiconductor memory device and method of forming the same, more particularly, to a non-volatile semiconductor memory device and method of forming the same.

2. Description of Related Art

A semiconductor memory device may be sorted into a volatile memory device in which stored data is extinguished when power supply is interrupted, and a non-volatile memory device in which stored data is retained when power supply is interrupted. The non-volatile memory device may also be sorted into a floating gate type and a charge trap type, depending on the type of data storage layer which constitutes a unit cell. The floating gate type memory device may be limited for higher integration and also may require increased power consumption. Therefore, the charge trap type memory device is being researched.

The charge trap type memory device may include a tunnel insulation layer, charge trap layer, blocking insulation layer and gate electrode stacked on a semiconductor substrate. A large negative voltage may be supplied to the gate electrode in order to perform an erase operation of releasing the trapped charge in the charge trap layer. During the erase operation, a so-called back tunneling occurs, where electrons tunnel from the gate electrode to the charge trap layer through the blocking insulation layer. As a result of the back tunneling, an erase may not be done completely and the speed of the erase operation may be delayed.

### SUMMARY

Example embodiments are related to a non-volatile memory device and method of forming the same. In example embodiments, a non-volatile memory device may include a tunnel insulation layer on a semiconductor substrate, a charge storage layer on the tunnel insulation layer, a first blocking insulation layer on the charge storage layer, and a gate electrode on the first blocking insulation layer, wherein the gate electrode includes aluminum and the first blocking insulation layer does not include aluminum.

In example embodiments, a method of forming a non-volatile memory device may include forming a tunnel insulation layer on a semiconductor substrate, forming a charge storage layer on the tunnel insulation layer, forming a first blocking insulation layer on the charge storage layer, and forming a gate electrode on the first blocking insulation layer, wherein the gate electrode includes aluminum and the first blocking insulation layer does not include aluminum.

### BRIEF DESCRIPTION OF THE DRAWINGS

Example embodiments will be more clearly understood from the following detailed description taken in conjunction with the accompanying drawings.

FIGS. 1 and 3-6D represent non-limiting, example embodiments as described herein.

FIG. 1 is a cross-sectional view illustrating a non-volatile memory device according to example embodiments.

FIGS. 2 and 3 are energy band diagrams of a conventional art and example embodiments, respectively.

FIGS. 4 and 5 are graphs illustrating effective work function (EWF) of a gate electrode according to example embodiments.

FIGS. 6A to 6D are cross-sectional views illustrating a method of fabricating a non-volatile memory device according to example embodiments.

It should be noted that these Figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION OF EXAMPLE EMBODIMENTS

Example embodiments will now be described more fully hereinafter with reference to the accompanying drawings, in which example embodiments are shown. Example embodiments, however, may be embodied in many different forms and should not be construed as limited to the embodiments set forth herein. Rather, these embodiments are provided so that this disclosure will be thorough and complete, and will fully convey the scope of example embodiments to those skilled in the art. Any element in a claim that does not explicitly state “means for” performing a specified function, or “step for” performing a specific function, is not to be interpreted as a “means” or “step” clause as specified in 35 U.S.C. § 112, paragraph 6. In particular, the use of “step of” in the claim herein is not intended to invoke the provisions of 35 U.S.C. § 112, paragraph 6. In the drawings, the thicknesses of layers and regions are exaggerated for clarity. It will also be understood that when a layer is referred to as being “on” another layer or substrate, it can be directly on the other layer or substrate, or intervening layers may also be present. Like reference numbers refer to like elements throughout.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein. Hereinafter, some example embodiments will be explained in detail with reference to the accompanying drawings.

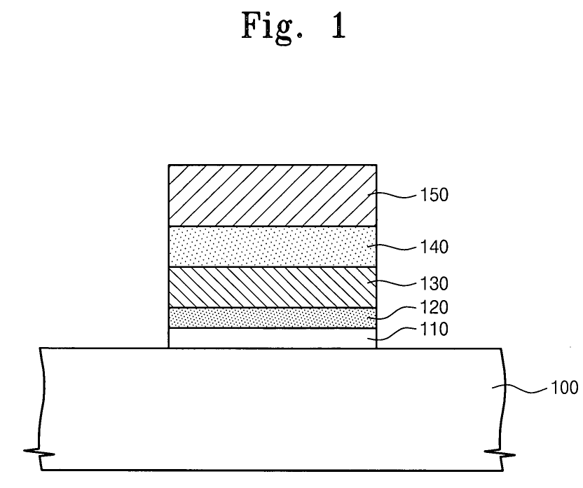

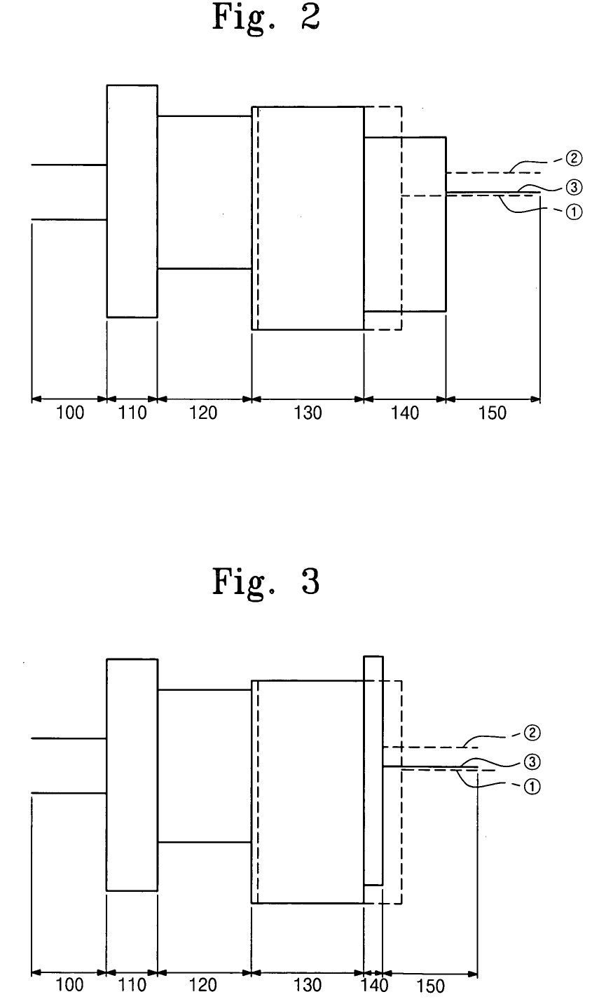

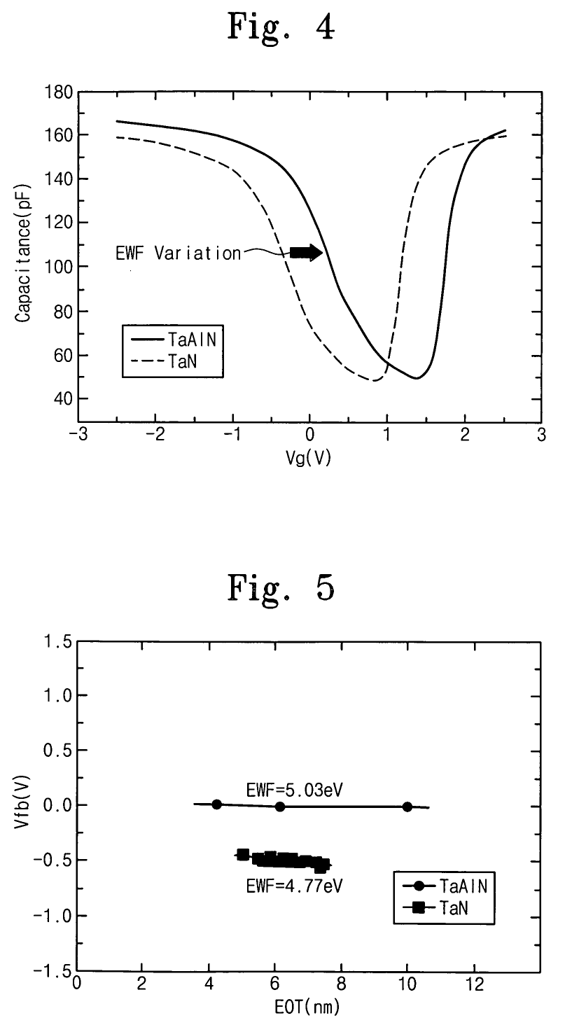

FIG. 1 is a cross-sectional view illustrating ay non-volatile memory device according to example embodiments. FIGS. 2 and 3 are energy band diagrams of a conventional art and example embodiments. Referring to FIG. 1, a tunnel insulation layer 110 may be disposed on a semiconductor substrate 100. The tunnel insulation layer 110 may include a silicon oxide layer. A charge storage layer 120 may be disposed on the tunnel insulation layer 110. The charge storage layer 120 may be made of an insulation layer including a relatively large amount of trap site or an insulation layer including nanoparticles. For example, the charge storage layer 120 may be made of a silicon nitride or a silicon nitride including conductive nanoparticles. Alternatively, the charge storage layer 120 may include a floating gate made of polysilicon.

A second blocking insulation layer 130 may be disposed on the charge storage layer 120. The second blocking insulation layer 130 may include aluminum oxide (Al₂O₃). A first blocking insulation layer 140 may be disposed on the second blocking insulation layer 130. The first blocking insulation layer 140 may not include aluminum. A gate electrode 150 may be disposed on the first blocking insulation layer 140. The gate electrode 150 may include aluminum.

In FIGS. 2 and 3, the solid lines are the band diagram according to example embodiments, and the dotted lines are the band diagram according to conventional art. \hat{1}, \hat{2}, and \hat{3} of FIGS. 2 and 3 indicate effective work function (EWF) of the gate electrode 150. In FIGS. 2 and 3, the conventional non-volatile memory device may have a structure including a tunnel insulation layer on a semiconductor substrate, a charge storage layer on the tunnel insulation layer, an aluminum oxide layer on the charge storage layer, and a gate electrode (e.g. TaN) on the aluminum oxide layer, sequentially stacked. \hat{1} indicates EWF of the conventional gate electrode.

Referring to FIG. 2, the first blocking insulation layer 140 may include a high-k material not containing aluminum. The first blocking insulation layer 140 may have a larger dielectric constant than the aluminum oxide layer. For example, the first blocking insulation layer 140 may include one selected from ZrO₂, HfO₂, ZrSiO₄, or HfSiO₄. As the first blocking insulation layer 140 has a larger dielectric constant than the aluminum oxide layer, the electrical field between the gate electrode 150 and the charge storage layer 120 may decrease. Accordingly, the back tunneling described above may be prevented or reduced.

The gate electrode 150 may be made of metal nitride including aluminum. For example, the gate electrode 150 may include one selected from TaAIN, TiAIN, WAIN, or MoAIN. As the gate electrode 150 includes aluminum, the effective work function (EWF) may become larger. In other words, in case the gate electrode 150 does not include aluminum, the EWF may become as small as \hat{2}. On the other hand, when the gate electrode 150 includes aluminum, the EWF may become as large as \hat{3}. Therefore, back tunneling may be prevented or reduced by using the gate electrode 150 having a relatively large EWF.

Referring to FIG. 3, the first blocking insulation layer 140 does not include aluminum, and may be an insulation layer having a larger energy band gap than the aluminum oxide layer. For example, the first blocking insulation layer 140 may be a silicon oxide layer. The back tunneling may be prevented or reduced as the potential barrier becomes higher by the first blocking insulation layer 140.

The gate electrode 150 may be made of metal nitride including aluminum. For example, the gate electrode 150 may include one selected from TaAIN, TiAIN, WAIN, or MoAIN. As the gate electrode 150 includes aluminum, EWF may become larger. In other words, when the gate electrode 150 does not include aluminum, the EWF may become as relatively small as \hat{2}, and when the gate electrode 150 includes aluminum, the EWF may become as relatively large as \hat{3}. Accordingly, the back tunneling may be prevented or reduced by the gate electrode 150 having a relatively large EWF.

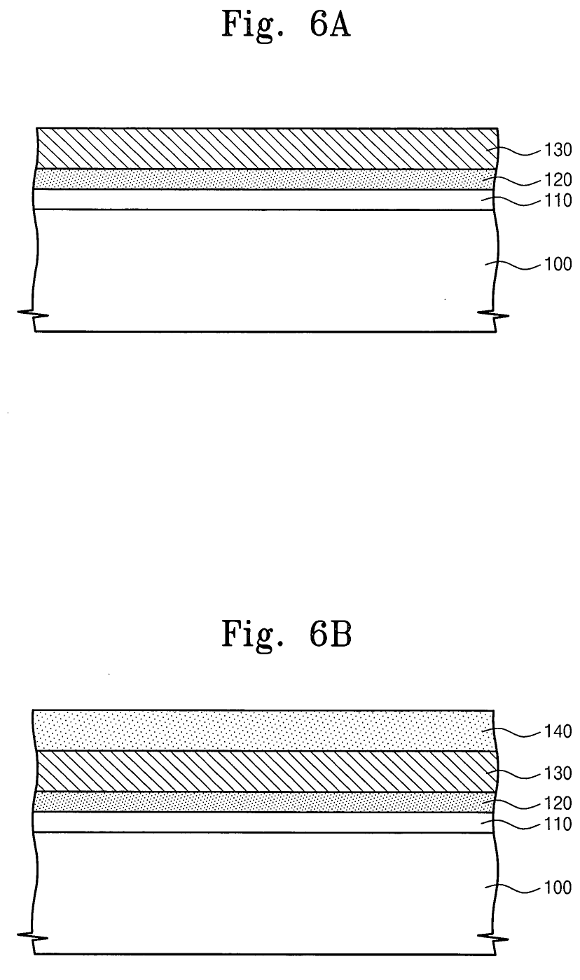

FIGS. 4 and 5 are graphs illustrating effective work function (EWF) of a gate electrode according to example embodiments. In FIG. 4, the x-axis indicates voltage Vg supplied to the gate electrode, and the y-axis indicates capacitance pF. Also, a solid line shows data according to example embodiments when the gate electrode is made of TaAIN, and a dotted line shows data according to conventional art when the gate electrode is made of TaN. In FIG. 5, the y-axis indicates flat band voltages Vfb, and the x-axis indicates equivalent oxide thickness EOT. Also, the line --shows data according to example embodiments when the gate electrode is made of TaAIN, and the line -▪-shows data according to the conventional art when the gate electrode is made of TaN. When the gate electrode 150 is made of metal nitride including aluminum, the back tunneling may be prevented or reduced as the EWF of the gate electrode 150 increases.

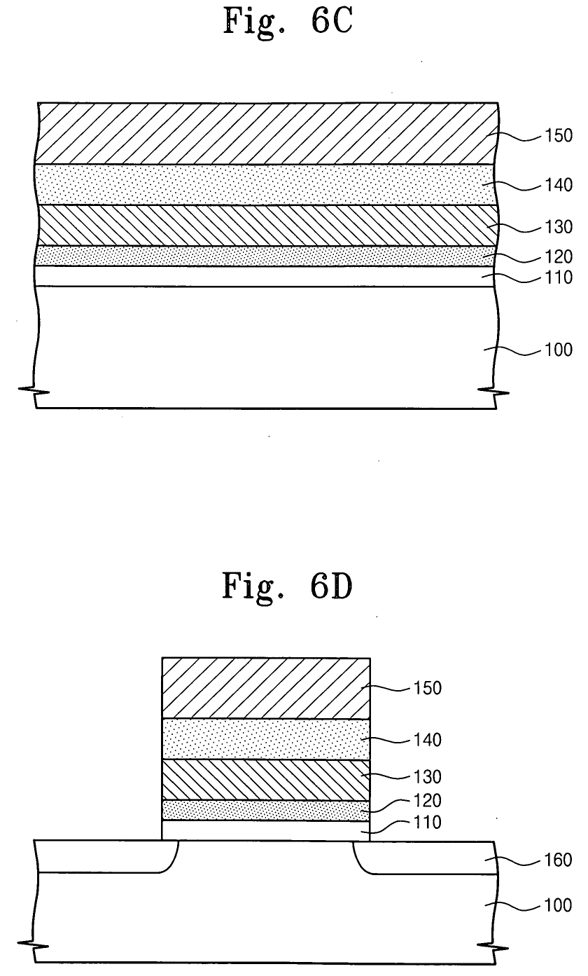

FIGS. 6A to 6D are cross-sectional views illustrating a method of fabricating a non-volatile memory device according to example embodiments. Referring to FIG. 6A, a tunnel insulation layer 110 may be formed on a semiconductor substrate 100. The tunnel insulation layer 110 may be formed by using a thermal oxidation process. A charge storage layer 120 may be formed on the tunnel insulation layer 110. The charge storage layer 120 may be made of silicon nitride. Alternatively, the charge storage layer 120 may be made of polysilicon. A second blocking insulation layer 130 may be formed on the charge storage layer 120. The second blocking insulation layer 130 may include aluminum oxide.

Referring to FIG. 6B, a first blocking insulation layer 140 may be formed on the second blocking insulation layer 130. The first blocking insulation layer 140 does not include aluminum. The first blocking insulation layer 140 may be made of a high-k material having a larger dielectric constant than the aluminum oxide. Therefore, in an erase operation, the back tunneling may be prevented or reduced by decreasing the electric field of the first blocking insulation layer 140. The first blocking insulation layer 140 may be one selected from ZrO₂, HfO₂, ZrSiO₄, or HfSiO₄.

Alternatively, the first blocking insulation layer 140 may be formed using an insulation layer, e.g. silicon oxide layer, having a larger band gap than the aluminum oxide layer. As a result, as the potential barrier becomes higher in an erase operation, the back tunneling may be prevented or reduced.

Referring to FIG. 6C, a gate electrode 150 may be formed on the first blocking insulation layer 140. The gate electrode 150 may be made of metal nitride including aluminum. For example, the gate electrode 150 may include one selected from TaAIN, TiAIN, WAIN, or MoAIN. The gate electrode 150 may be formed by chemical vapor deposition method or sputtering method, which utilize aluminum source. Alternatively, the gate electrode 150 may be made by forming the metal nitride and injecting aluminum ion, or by forming an aluminum layer and diffusing. As the gate electrode 150 includes aluminum, the effective work function may increase to result in preventing or reducing the back tunneling.

Referring to FIG. 6D, a mask pattern (not shown) may be formed on the gate electrode 150, and an etch process may be performed by using the mask pattern as mask, to sequentially pattern the gate electrode 150, first blocking insulation layer 140, second blocking insulation layer 130, charge storage layer 120, and tunnel insulation layer 110. An ion injection process may be performed by using the gate electrode 150 as mask, to form source/drain regions 160.

According to example embodiments, only the gate electrode may include aluminum, among the gate electrode and the first blocking insulation layer. The back tunneling may be prevented or reduced as the EWF of the gate electrode is increased. The back tunneling may be prevented or reduced by the first blocking insulation layer including a high-k material or having a relatively large band gap. Accordingly, the erase speed of a non-volatile memory device may be enhanced.

Although example embodiments have been described in connection with example embodiments illustrated in the accompanying drawings, it is not limited thereto. It will be apparent to those skilled in the art that various substitution, modifications and changes may be thereto without departing from the scope and spirit of the following claims.

What is claimed is:

1. A non-volatile memory device comprising:
a tunnel insulation layer on a semiconductor substrate;
a charge storage layer on the tunnel insulation layer;
a first blocking insulation layer on the charge storage layer; and
a gate electrode on the first blocking insulation layer,
wherein the gate electrode includes aluminum and the first blocking insulation layer does not include aluminum.

2. The non-volatile memory device of claim 1, wherein the first blocking insulation layer includes a high-k material layer not containing aluminum, and the high-k material layer has a higher dielectric constant than an aluminum oxide layer.

3. The non-volatile memory device of claim 2, wherein the high-k material layer includes one of ZrO₂, HfO₂, ZrSiO₄, or HfSiO₄.

4. The non-volatile memory device of claim 1, wherein the first blocking insulation layer has a larger band gap than an aluminum oxide layer, and does not include aluminum.

5. The non-volatile memory device of claim 4, wherein the first blocking insulation layer includes silicon oxide.

6. The non-volatile memory device of claim 1, wherein the gate electrode includes metal nitride.

7. The non-volatile memory device of claim 6, wherein the gate electrode includes one of TaAIN, TiAIN, WAIN, or MoAIN.

8. The non-volatile memory device of claim 1 further comprising:
a second blocking insulation layer between the first blocking insulation layer and the charge storage layer.

9. The non-volatile memory device of claim 8, wherein the second blocking insulation layer includes aluminum oxide.

10. The non-volatile memory device of claim 1, wherein the charge storage layer includes silicon nitride.

11. The non-volatile memory device of claim 1, wherein the charge storage layer includes polysilicon.

12. A method of forming a non-volatile memory device comprising:
forming a tunnel insulation layer on a semiconductor substrate;
forming a charge storage layer on the tunnel insulation layer;
forming a first blocking insulation layer on the charge storage layer; and
forming a gate electrode on the first blocking insulation layer, wherein
wherein the gate electrode includes aluminum and the first blocking insulation layer does not include aluminum.

13. The method of claim 12 further comprising:
forming a second blocking insulation layer between the first blocking insulation layer and the charge storage layer.

14. The method of claim 13, wherein the second blocking insulation layer includes aluminum oxide.

15. The method of claim 12, wherein the first blocking insulation layer is made of a high-k material having a larger dielectric constant than aluminum oxide.

16. The method of claim 15, wherein the first blocking insulation layer includes one of ZrO₂, HfO₂, ZrSiO₄, or HfSiO₄.

17. The method of claim 12, wherein the first blocking insulation layer is made of an insulation material having a larger band gap than aluminum oxide.

18. The method of claim 17, wherein the first blocking insulation layer is made of silicon oxide.

19. The method of claim 12, wherein the gate electrode is made of metal nitride.

20. The method of claim 15, wherein the gate electrode is made of one of TaAIN, TiAIN, WAIN, or MoAIN.
